(19) United States
(12) Patent Application Publication
(10) Pub. No.: US 2023/0096503 A1
(43) Pub. Date: Mar. 30, 2023

(54) HIGH RESOLUTION VNIR LENS

(71) Applicant: BAE Systems Information and Electronic Systems Integration Inc., Nashua, NH (US)

(72) Inventors: Mark L. Oskotsky, Mamaroneck, NY (US); Jacob D. Garan, Honolulu, HI (US); Morgan Jolley, Commack, NY (US); Daniel N. Kokubun, Waipahu, HI (US); Michael J. Russo, Roslyn, NY (US)

(73) Assignee: BAE Systems Information and Electronic Systems Integration Inc., Nashua, NH (US)

(21) Appl. No.: 17/487,758

(22) Filed: Sep. 28, 2021

(51) Int. Cl. G02B 13/14; G02B 13/06; H01L 27/146

(52) U.S. Cl. CPC G02B 13/14; G02B 13/06; H01L 27/14627

(57) ABSTRACT

An athermal and achromatic lens with a high resolution while further being near orthoscopic and providing a large field of view. Further, the provided VNIR lens may utilize only three types of optical glass allowing the lens to be reduced in size, cost, and weight while further reducing or minimizing the complexity thereof.

### STATEMENT OF GOVERNMENT INTEREST

This invention was made with government support under Contract No. N00014 18 C 2050 awarded by the United States Navy. The government has certain rights in the invention.

### TECHNICAL FIELD

The present disclosure relates generally to the field of orthoscopic imaging optics working within the visible and near infrared (VNIR) spectrums. More particularly, in one example, the present disclosure relates to an orthoscopic and achromatic lens working in a wide VNIR spectrum while maintaining a low focal ratio. Specifically, in another example, the present disclosure relates to an orthoscopic and achromatic lens in the VNIR spectrum having a low focal ratio that is further corrected from monochromatic and chromatic aberrations over the VNIR spectrum while further being passively athermal.

### BACKGROUND

Imaging performed in the visible and near infrared (VNIR) spectrum is commonly utilized for remote passive sensing applications. For example, VNIR lenses may be deployed by airborne platforms for detection and identification of buried objects, foreign materials, or structures hidden within or beneath a layer of material or substrate, further utilizing processes such as shearography or the like. Similarly, VNIR imaging lenses may be deployed for detection of minor or nearly imperceptible distortions or flaws in what appears to be an otherwise uniform surface.

As these lenses are typically employed in airborne platforms, they are often subjected to a large temperature range with rapid temperature fluctuations as aircraft operate and/or move to various altitudes. Current VNIR lenses and systems tend to include systems that are selected to correct or compensate for specific aspects but are unable or incapable of correcting for all desired performance parameters. For example, current lenses may compensate for thermal fluctuation but are unable to achieve a low focal ratio and maintain a wide field of view. Other current lenses may similarly address chromatic aberrations, again suffering from an inability to be applied with a low focal ratio and/or wide field of view. Still other lenses may provide for a wide field of view but may not be telecentric or may not properly compensate for chromatic and/or thermal aberrations. Therefore, it is common that current lenses are selected to provide athermal and/or achromatic but do not provide a high resolution or wide field of view. Alternatively, current lenses may provide a higher resolution and wide field of view but suffer from chromatic and/or thermal aberrations making the current lenses available less than ideal for remote and airborne applications.

Current VNIR lenses and systems include:
U.S. Pat. No. 8,274,743;
Paper “Multilens system design with an athermal chart” (1 Dec. 1994/Vol. 33, No. 34/APPLIED OPTICS) by Yasuhisa Tamagawa, Satoshi Wakabayashi, Toru Tajime, and Tsutomu Hashimoto;
U.S. Pat. No. 10,620,408;
U.S. Patent Application 2009/0296201;
U.S. Patent Application No. 2012/0147483;
U.S. Pat. No. 6,038,078; and
U.S. Pat. No. 5,905,596.

### SUMMARY

Each of the identified current lenses suffers from one or more of the shortcomings described above. In particular, U.S. Pat. No. 8,274,743 B2 (Sep. 25, 2012) discloses thermally compensating lens for high power lasers. The disclosed lens consists of two components and is athermal by combining glasses with negative and positive dn/dT. The lens works with a collimated laser beam but it does not have a low focal ratio and wide field of view.

The paper “Multilens system design with an athermal chart” by Yasuhisa Tamagawa, Satoshi Wakabayashi, Toru Tajime, and Tsutomu Hashimoto describes an athermal chart that plots chromatic dispersive power and thermal dispersive power on a Cartesian coordinate in order to address chromatic and thermal aberration only for doublet or triplet configurations. This technique cannot be applied to the low focal ratio, wide field of view multi-components lenses.

Another example of a VNIR orthoscopic lens is disclosed in U.S. Pat. No. 10,620,408 (Apr. 4, 2020). Lens is corrected over the 2450 nm-450 nm bandwidth and has a wide field of view 5.56° vertical and 66° horizontal. Lens consists of 8 elements and is not nearly telecentric. Also focal ratio is 4, so a required diffraction resolution of 3.45 μm cannot be achieved.

Yet another variety of lenses is disclosed in US Patent Application 2009/0296201 A1 (Dec. 3, 2009). The disclosed lenses are corrected over the wide set of spectrums and are not nearly telecentric and orthoscopic. Further, they do not provide a required resolution in the VNIR region of spectrum.

U.S. Patent Application No. 2012/0147483 A1 discloses wide field of view athermalized orthoscopic lens which is stable over a wide range of temperatures; however, the lens is not nearly telecentric and has high focal ratio of 7.4. Therefore, the disclosed lens cannot provide the required resolution.

Another telecentric projection lens designed for the visible spectrum (not the VNIR spectrum) is disclosed in U.S. Pat. No. 6,038,078 (Mar. 14, 2000). The disclosed lens is not athermal and works with a special prism which compensates for spherical aberration of the elements with optical power.

Yet another telecentric projection lens is disclosed in U.S. Pat. No. 5,905,596 (May 18, 1999). The disclosed lens is not orthoscopic and its spherical aberration is compensated by the spherical aberration induced by a beamsplitter.

The present disclosure addresses these and other issues by providing an athermal and achromatic lens with a high resolution while further being near orthoscopic and providing a large field of view. Further, the provided VNIR lens may utilize only three types of optical glass allowing the lens to be reduced in size, cost, and weight while further reducing or minimizing the complexity thereof.

In one aspect, an exemplary embodiment of the present disclosure may provide a visible and near infrared (VNIR) lens assembly comprising: a plurality of first optical elements, each having a positive optical power; a plurality of second optical elements, each having a negative optical power; a physical aperture stop in front of the plurality of first and second optical elements; and an image detector behind the plurality of first and second optical elements; wherein at least one optical element of the plurality of first optical elements is formed of a first optical glass type, at least another optical element of the plurality of first optical elements is formed of a second optical glass type, and at least one of the plurality of second optical elements is formed of a third optical glass, wherein none of the plurality of second optical elements are formed of the first or second glass types. This exemplary embodiment or another exemplary embodiment may further provide wherein the first and second plurality of optical glasses further comprises: eight total optical elements with five optical elements in the first plurality of optical elements having a positive optical power and three optical elements in the second plurality of optical elements having a negative optical power. This exemplary embodiment or another exemplary embodiment may further provide wherein the eight total optical elements of the first and second plurality of optical elements are arranged in order from the aperture to the image detector as a first optical element having a positive optical power, a second optical element having a negative optical power, a third optical element having a positive optical power, a fourth optical element having a negative optical power, a fifth optical element having a positive optical power, a sixth optical element having a positive optical power, a seventh optical element having a negative optical power, and an eighth optical element having a positive optical power. This exemplary embodiment or another exemplary embodiment may further provide wherein: the first optical glass type further comprises a fluor crown optical glass; the second optical glass type further comprises a dense flint optical glass; and the third optical glass type further comprises a crownflint optical glass. This exemplary embodiment or another exemplary embodiment may further provide wherein the first, fifth, and sixth optical elements are made from the first optical glass type, the third and eighth optical elements are made from the second optical glass type, and the second, fourth, and seventh optical elements are made from the third optical glass type. This exemplary embodiment or another exemplary embodiment may further provide wherein the first optical glass type is Schott optical glass N-FK58, the second optical glass type is Schott optical glass N-SF57HTUltra, and the third optical glass type is Schott optical glass N-KF9. This exemplary embodiment or another exemplary embodiment may further provide wherein the first optical element further comprises: a double convex lens having a first surface oriented towards the aperture stop and a second surface opposite therefrom. This exemplary embodiment or another exemplary embodiment may further provide wherein the second optical element further comprises: a double concave lens having a first surface oriented towards the aperture stop and a second surface opposite therefrom. This exemplary embodiment or another exemplary embodiment may further provide wherein the third optical element further comprises: a positive meniscus lens having a first surface oriented towards the aperture stop and a second surface opposite therefrom; wherein the second surface of the third optical element is a concave surface of the positive meniscus. This exemplary embodiment or another exemplary embodiment may further provide wherein the fourth optical element further comprises: a double concave lens having a first surface oriented towards the aperture stop and a second surface opposite therefrom; wherein the second surface of the fourth optical element is aspherical. This exemplary embodiment or another exemplary embodiment may further provide wherein the fifth optical element further comprises: a double convex lens having a first surface oriented towards the aperture stop and a second surface opposite therefrom. This exemplary embodiment or another exemplary embodiment may further provide wherein the sixth optical element further comprises: a double convex lens having a first surface oriented towards the aperture stop and a second surface opposite therefrom. This exemplary embodiment or another exemplary embodiment may further provide wherein the seventh optical element further comprises: a double concave lens having a first surface oriented towards the aperture stop and a second surface opposite therefrom; wherein the first surface of the seventh optical element is aspherical. This exemplary embodiment or another exemplary embodiment may further provide wherein the eighth optical element further comprises: a positive meniscus lens having a first surface oriented towards the aperture stop and a second surface opposite therefrom; wherein the second surface of the eighth optical element is a concave surface of the positive meniscus and is aspherical. This exemplary embodiment or another exemplary embodiment may further provide wherein the lens assembly further comprises: an orthoscopic lens with residual distortion not exceeding 0.5% over a full field of view; an overall length less than 100 mm as measured from the first element to the image detector; and a focal point ratio of 2.8. This exemplary embodiment or another exemplary embodiment may further provide wherein the lens assembly is achromatic over a spectral range from 870 nm to 400 nm, is passively athermal for the range of −14° C. to 70° C., and has a resolution of 3.45 micrometers at the image detector.

In another aspect, an exemplary embodiment of the present disclosure may provide a method comprising: receiving light through a physical aperture stop of a lens assembly; directing the light through a first plurality of optical elements, wherein each optical element of the first plurality of optical elements has a positive optical power with at least one element of the first plurality of optical elements formed of a first optical glass type and at least another element of the first plurality of optical elements formed of a second optical glass type; directing the light through a second plurality of optical elements, wherein each optical element of the first plurality of optical elements has a negative optical power with at least one of the second plurality of optical elements formed of a third optical glass type, wherein none of the plurality of second optical elements are formed of the first or second glass types; detecting the light with an image detector; and generating an image from the image detector. This exemplary embodiment or another exemplary embodiment may further provide wherein directing the light through the first and second pluralities of optical elements further comprises: directing the light through a first optical element having a double convex shape and a positive optical power; directing the light through a second optical element having a double concave shape and a negative optical power; directing the light through a third optical element having a positive meniscus shape and a positive optical power, the third optical element having a first surface and a second surface wherein the second surface is a concave surface of the positive meniscus; directing the light through a fourth optical element having a double concave shape and a negative optical power, wherein a second surface of the fourth optical element is aspherical; directing the light through a fifth optical element having a double convex shape and a positive optical power; directing the light through a sixth optical element having a double convex shape and a positive optical power; directing the light through a seventh optical element having a double concave shape and a negative optical power, wherein a first surface of the seventh optical element is aspherical; and directing the light through an eighth optical element having a double convex shape and a positive optical power, the eighth optical element having a first surface and a second surface wherein the second surface is a concave surface of the positive meniscus and is aspherical. This exemplary embodiment or another exemplary embodiment may further provide wherein the lens assembly further comprises: an orthoscopic lens with residual distortion not exceeding 0.5% over a full field of view; an overall length less than 100 mm as measured from the first element to the image detector; and a focal point ratio of 2.8; wherein the lens assembly is achromatic over a spectral range from 870 nm to 400 nm, is passively athermal for the range of −14° C. to 70° C., and has a resolution of 3.45 micrometers at the image detector. This exemplary embodiment or another exemplary embodiment may further provide wherein the first, fifth, and sixth optical elements are made from the first optical glass type, the third and eighth optical elements are made from the second optical glass type, and the second, fourth, and seventh optical elements are made from the third optical glass type.

In yet another aspect, an exemplary embodiment of the present disclosure may provide a visible and near infrared (VNIR) orthoscopic lens assembly comprising: a physical aperture stop defining an entrance pupil; a first optical element having a positive optical power, the first optical element being a double convex lens; a second optical element having a negative optical power, the second optical element being a double concave lens; a third optical element having a positive optical power, the third optical element being positive meniscus lens having a first surface oriented towards the aperture stop and a second surface opposite therefrom, wherein the second surface of the third optical element is a concave surface of the positive meniscus; a fourth optical element having a negative optical power, the fourth optical element being a double concave lens having a first surface oriented towards the aperture stop and a second surface opposite therefrom, wherein the second surface of the fourth optical element is aspherical; a fifth optical element having a positive optical power, the fifth optical element being a double convex lens; a sixth optical element having a positive optical power, the sixth optical element being a double convex lens; a seventh optical element having a negative optical power, the seventh optical element being a double concave lens having a first surface oriented towards the aperture stop and a second surface opposite therefrom, wherein the first surface of the seventh optical element is aspherical; an eighth optical element having a positive optical power, the eighth optical element being a positive meniscus lens having a first surface oriented towards the aperture stop and a second surface opposite therefrom, wherein the second surface of the eighth optical element is a concave surface of the positive meniscus and is aspherical; and an image detector; wherein the lens assembly has an overall length less than 100 mm as measured from the first optical element to the image detector and a focal point ratio of 2.8; and wherein the lens assembly is achromatic over a spectral range from 870 nm to 400 nm and is passively athermal for the range of −14° C. to 70° C.

### BRIEF DESCRIPTION OF THE SEVERAL VIEWS OF THE DRAWINGS

Sample embodiments of the present disclosure are set forth in the following description, are shown in the drawings and are particularly and distinctly pointed out and set forth in the appended claims.

FIG. 1 (FIG. 1) is a schematic view of an exemplary visible and near infrared (VNIR) lens according to one aspect of the present disclosure.

FIG. 2 (FIG. 2) is a wavefront analysis graph for the lens of FIG. 1 according to one aspect of the present disclosure.

FIG. 3 (FIG. 3) is a diffraction modulation transfer function (MTF) data graph as gathered from the lens of FIG. 1, according to one aspect of the present disclosure.

FIG. 4A (FIG. 4A) shows a graph of the astigmatism of the lens from FIG. 1, according to one aspect of the present disclosure.

FIG. 4B (FIG. 4B) shows a graph of the distortion of the lens from FIG. 1, according to one aspect of the present disclosure.

FIG. 5 (FIG. 5) shows a chromatic focus shift for the lens from FIG. 1, according to one aspect of the present disclosure.

FIG. 6 (FIG. 6) shows the lateral color across the field of view for the lens from FIG. 1, according to one aspect of the present disclosure.

FIG. 7 (FIG. 7) shows the telecentricity across the field of view for the lens from FIG. 1, according to one aspect of the present disclosure.

FIG. 8 (FIG. 8) shows the illumination uniformity across the field of view for the lens from FIG. 1, according to one aspect of the present disclosure.

FIG. 9 (FIG. 9) shows the thermal MTF across the field of view and across the temperature range for the lens from FIG. 1, according to one aspect of the present disclosure.

### DETAILED DESCRIPTION

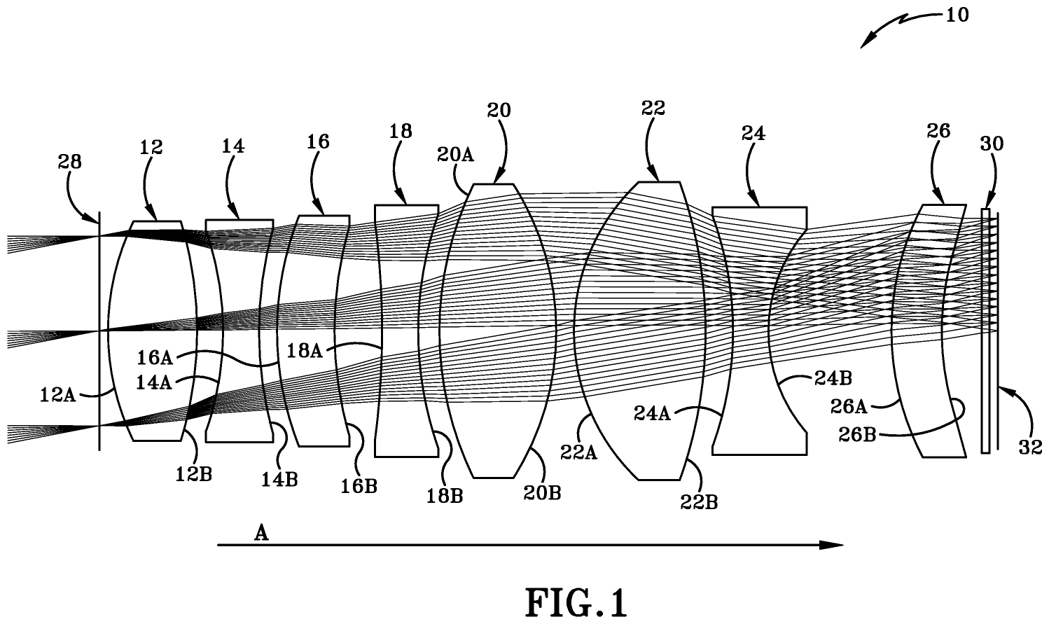

With reference to FIG. 1, a visible and near infrared (VNIR) imaging lens assembly is shown at reference 10. Generally speaking, lens assembly 10 may include several optical elements, namely, a first optical element 12, second optical element 14, third optical element 16, fourth optical element 18, fifth optical element 20, a sixth optical element 22, seventh optical element 24, and an eighth optical element 26. Lens assembly 10 may further include an aperture stop 28, a window 30, and a sensor 32 which may be a focal plane array (FPA) 32, or the like.

Generally, and as discussed in further detail below, lens assembly 10 may be an achromatic, orthoscopic, and athermal VNIR imaging lens operable within the wide VNIR spectrum ranging from approximately 870 nanometers to 400 nanometers. Lens assembly 10 may provide a high resolution undistorted image and may further be passively athermal in a range of −14° C. to 70° C.

As best seen in FIG. 1, the first through eighth elements 12-26 may be determined by their position within lens assembly 10 based on the order in which each element may encounter light entering into lens assembly 10. Specifically, as indicated by arrow A in FIG. 1, light may enter through aperture stop 28 and pass through each element 12-26 before encountering window 30 and FPA 32. Accordingly, each element may be numbered relative to their position in this path; however, it will be understood that any numbering convention may be employed, as desired. Although first optical element 12 through eighth optical element 26 may be constructed of any suitable material, it is contemplated that each optical element will be formed of one of three types of optical glass found to impart the desired properties into lens assembly 10. Accordingly, as detailed below, each optical element 12-26 may be formed of commercially available Schott optical glass N-FK58, N-KF9, or N-SF57HTUltra. The combination of these three specific optical glasses may provide optimal conditions for the lens chromatic and thermal correction. First through eighth optical elements 12-26 may include any suitable or necessary treatments or coatings, including, but not limited to, anti-reflective coatings or the like.

Accordingly, first optical element 12 may include a first surface 12A, which may be the first surface oriented towards the aperture stop 28 and the first surface to encounter light entering into lens assembly 10. First optical element 12 may further include a second surface 12B opposite first surface. According to one aspect, first optical element 12 may be a double-convex optical lens and may have or provide a positive optical power. First optical element 12 may be formed of Schott Optical Glass N-FK58.

Second optical element 14 may likewise include a first surface 14A and a second surface 14B opposite therefrom. Second optical element 14 may have a negative optical power and may be constructed as a double-concave lens formed of Schott Optical Glass N-KF9.

Third optical element 16 may likewise include a first surface 16A and a second surface 16B opposite therefrom. Third optical element 16 may have a positive optical power and may be shaped as a positive meniscus with second surface 16B being the concave surface which may be the surface oriented away from the light source and/or aperture stop 28 and oriented towards or facing the FPA 32. Third optical element 16 may be formed of Schott Optical Glass N-SF57HTUltra.

Fourth optical element 18 may include a first surface 18A and a second surface 18B opposite therefrom and may have a negative optical power. Fourth optical element 18 may take the shape of a double-concave lens and may be formed from Schott Optical Glass N-KF9. Second surface 18B of fourth optical element 18 may be aspherical in order to compensate for wide beam off-axis spherical aberration comas induced by first element 12, second element 14, and third element 16. The aspherical nature of second surface 18B is discussed further below.

Fifth optical element 20 may have a first surface 20A and a second surface 20B and a negative optical power. Fifth optical element 20 may be a double-convex lens made from Schott Optical Glass N-FK58.

Sixth optical element 22 may likewise have a first surface 22A and a second surface 22B opposite therefrom. Sixth optical element 22 may have a positive optical power and may be a double-convex lens made from Schott Optical Glass N-FK58.

Seventh optical element 24 may likewise have a first surface 24A and a second surface 24B and may have a negative optical power. Seventh optical element 24 may be a double-concave lens made from Schott Optical Glass N-KF9 with first surface 24A being aspherical to compensate for pupil spherical aberration, tangential astigmatism, and coma introduced from the previous optical elements 12-22.

Eighth optical element 26 may similarly have a first surface 26A and a second surface 26B opposite therefrom. Eighth optical element 26 may have a positive optical power and may be a positive meniscus. Second surface 26B may form the concave surface oriented towards the FPA 32 and may further be aspherical in order to compensate for residual distortion and astigmatism.

The optical powers and shape of each of first optical element 12 through eighth optical element 26 may be selected, along with the Abbe dispersion values and thermal powers of the optical material, to provide that lens assembly 10 is athermalized over a wide range of temperatures and is nearly telecentric and orthoscopic while correcting for monochromatic and chromatic aberrations, as discussed further below.

With continued reference to FIG. 1, first through eighth optical elements 12-26 are numbered and arranged such that first optical element 12 is adjacent to or closest to aperture stop 28 while eighth optical element 26 is closest to and/or adjacent to window 30 and FPA 32. Accordingly, it will be understood that these optical elements are numbered in order from aperture stop 28 to window 30 and FPA 32 but may be numbered in any other suitable order or position. Generally, lens assembly 10 may include a housing or similar structure containing each of the components described herein, as dictated by the desired implementation. Such housing is not shown in FIG. 1 but may be included in any suitable position, shape, form, and/or with any desired additional features, as dictated by the desired implementation.

Aperture stop 28 may be a standard and/or commercially available aperture and may be fixed, adjustable, or any other suitable aperture style and type as desired, according to the specific implementation of lens assembly 10. As used herein, aperture stop 28 may include or be the entrance pupil for lens assembly 10 and may further define the field of view of lens assembly 10.

Similarly, window 30 may be any suitable and/or commercially available window 30 and may be integral to or form a part of the imaging detector (FPA 32), as dictated by the desired implementation. Window 30 may have a first side 30A and a second side 30B and may be constructed of any suitable material. According to one aspect, window 30 may be constructed of sapphire glass.

FPA 32 itself may be any suitable optical detector of any type appropriate for the desired implementation. According to one aspect, FPA 32 may be a fine resolution detector with a 3.45 micrometer pitch. In other words, FPA 32 may be a pixel array with a pixel size of 3.45 micrometers for use in high resolution and wide area imaging applications.

Lens assembly 10 may further include any other suitable elements or components as necessary for the operation thereof. Specifically, in one example, lens assembly 10 may include or otherwise be in communication with one or more processors which may be a computer, a processor, a logic, a logic controller, a series of logics, or the like which may include or be in further communication with one or more non-transitory storage mediums and may be operable to both encode and/or carry out a set of encoded instructions contained thereon. Further, according to this example, a processor may control any moving parts of lens assembly 10 such as an adjustable aperture or the like and may further process any imaging obtained by FPA 32 and lens assembly 10, generally. Such a processor may be in further communications with other systems such as other computers or systems carried alongside or along with lens assembly 10, as dictated by the desired implementation. According to one aspect, lens assembly 10 is contemplated for use in an airborne platform and therefore may be integrated with, or in further communication with, any necessary or desired platform systems, as dictated by the desired implementation.

Similarly, lens assembly 10 may further be in operable communication with an operator or user, including those remote from lens assembly 10, for overseeing the operation thereof. Further, such an operator may be notified or otherwise provided with imaging obtained from lens assembly 10 and FPA 32, as discussed further below.

Having generally described the elements and components of lens assembly 10, these elements and components will now be described in more detail with reference to the exemplary embodiment of lens assembly 10 shown in FIG. 1. The specifications for the lens assembly 10 of FIG. 1 is as follows:

| | |
|---|---|
| EFL, mm | 66 |
| F# | 2.8 |
| WL, nm | 870-400 |
| FFOV, Image plane, mm | 27.8 |
| FFOV, object space, deg. | 24 |
| Pixel size, μm | 3.45 |
| OAL, mm | <100 |
| Distortion, % | <0.5 |
| Telecentricity, deg. | <10 |
| Temperature range, deg. C | −14 to +70 |
| Operational Altitude | sea level-5 Kft |
| Non-Operational Altitude | sea level-40 Kft |
| MTF across the field over the temperature range | >0.3 |

Generally speaking, optical lenses are subjected to chromatic and thermal aberrations due to the changes in wavelength/spectrum and temperature/environment. In particular, variation in ambient temperature causes changes in refractive index, radius of curvature, thickness of the lens, and air spacing. This temperature variation can significantly degrade the image quality. Therefore, a refractive lens system utilized across a wide spectrum and in variable environmental conditions needs to have a stable performance over the specified waveband and temperature ranges. It is well known that optical glass materials have thermal properties that change the focal length of a lens when the environmental temperature changes. In particular, the thermal coefficient of expansion (CTE) a and thermal change in index of refraction dn/dT as a function of temperature T (dn/dT) affect the optical power of a lens.

The optical power of a single lens is influenced by these two properties and is called the thermal power Ψp of a lens:

Ψp=(((dn/dT)/(n−1)−a))

The optical power of a lens is therefore a function of temperature according to the following equation:

Δϕ=ϕ(((dn/dT)/(n−1)−a)),

where ϕ is the optical power of the lens. The change Δϕ in the optical power is the original power of the lens times the thermal power of the lens Ψp. Δϕ=ϕΨp.

The chromatic power φ of a lens is the inverse of its abbe value V:

φ=((nmin−nmax)/(nc−1)),

where the subscripts on the index values refer to the relative refractive index measured at the minimum, center, and maximum wavelengths, respectively. The wavelength values are determined by the defined wavelengths.

Athermalization is necessary for the optics working in the variable temperature environment and may be provided along with achromatization properties of the lens as well. Specifically, providing for the doublet achromatization and athermalization may occur by solving three simultaneous equations:

ϕ=ϕ1+ϕ2

Δϕ=φ1*ϕ1+φ2*ϕ2

dϕ/dT=Ψ1*ϕ1+Ψ2*ϕ2

where ϕ is the power of the lens system, ϕ₁ and ϕ₂ are the powers of the individual lens elements; ϕ₁ and ϕ₂ are the chromatic powers of each element and Ψ₁ and Ψ₂ are the thermal powers of the elements.

To solve these three equations simultaneously with two glasses requires selection of glasses that lie along a line that also crosses the origin of the athermal glass map. This reference line may be drawn on the map by selecting a reference glass, which defines one point on the line, while the other point is the origin of the map. Further, the CTE of any housing material and/or spacing materials between optical elements should be taken into account and included in the above equations.

In the optical system comprising K thin components separated by spacers, the total optical power ϕT is provided by:

$$ϕ T = {{\sum }_{i = 1}}^{k} ( hi / h 1 ) ϕ i$$

where hi is the paraxial ray height at the component i and h1 is the paraxial ray height at the first component or at the entrance pupil located in front of the optical system.

For the multi-component lens relations between the chromatic and thermal material properties, heights of the rays at the components, component optical powers, and preferred shapes can be complicated and are non-linear.

Current methods of correction available to athermalize optical systems can be generally distilled down to three general methods: (1) thermal correction, wherein the optical system may be held at a constant temperature independent of the external environment using a thermostatically controlled housing around the optical system; (2) active thermal compensation wherein a motor is used for thermal focus shift compensation; and (3) athermilized systems using passive thermal correction wherein the optical design can be performed within the controlling thermal aberrations. With regards to athermalized systems using passive thermal correction, there is low sensitivity to temperature changes and the performance of these passively athermalized systems does not change within a pre-determined temperature range. Put another way, the CTE of the materials in a passive athermalized system can be accounted for to provide an allowable change to the focal length of the lens within the operating temperature range. The allowable change of the focal length should lie within the depth of focus of the optical system overall, thus making the system passively athermal.

Accordingly, such passive athermalization may be accomplished by careful selection of the materials of the optical elements, hence the use of only three specific glasses for the construction of optical elements 12-26 of lens system 10. Optical elements 12-26, as discussed herein, may be combined in a particular order make the lens insensitive to changes in temperature. No moving parts are thus employed, but very careful attention needs to be paid to the selection of the types of glass used and the material used to manufacture the mechanical spacers as the impact of athermalization is based on the types of optical material and mechanical spacers material that are used.

In order to design an athermal optical system the necessary combination of different materials with special relations between their material expansion coefficients and refractive indices must be determined. Some glasses (e.g. fluor crown (FK) and phosphate crown (PK) glass (commercially available from Schott, OHARA, or others)) have been specifically manufactured to have small or negative γ values to address the thermalization problem. Others may provide known effects on the light entering lens assembly 10 including, for example, crownflint “N” and dense flint optical glasses. For these reasons, the lens assembly 10 and optical elements 12-26 thereof have been selected from Schott optical glass N-FK58 (FK type), N-KF9 (Crownflint type), and N-SF57HTUltra (dense flint type), as described previously herein.

Additionally, as alluded to above, the refractive index change associated with changes in temperature of lens assembly 10 is not uniform across the spectrum and further depends on the specific wavelength, which may induce thermal chromatic aberration into the lens assembly 10.

In particular, as the temperature conditions change, the shapes and positions of the optical elements 12-26 in lens assembly 10 will also change. This may further cause the focal length and position of the image on the FPA 32 to change as well. These changes, although minute, may have a significant impact on lens assembly's 10 performance. If the lens assembly 10 is not athermal in order to compensate for these changes the FPA 32 has to be adjusted along the optical axis or some of the optical elements 12-26 inside the lens assembly 10 would have to be moved. This is highly undesirable as it would require additional hardware, electronics, and software to perform and monitor necessary adjustments.

Again, however, lens assembly 10 does not need physical thermal adjustments when the change of the focus position within the required temperature range stays inside the depth of focus of the lens. Diffraction depth of focus (DOF) is defined by:

DOF=λ/NA²

Where λ is the wave length and NA is numerical aperture at the image space.

For λ=550 nm and F #2.8 (NA=0.179), which is representative of lens assembly 10 as described and shown herein, the DOF≅0.017 mm. Thus, lens assembly 10 is passively athermal and performance is stable for all temperature changes inside 0.017 mm. If all temperature changes to the lens assembly 10 stay within this 0.017 mm DOF, no refocusing would be required.

For lens assembly 10, according to one aspect, the following relations among the optical elements optical powers, material and thermal powers have been found to achieve monochromatic and achromatic aberrational correction across the field while the VNIR lens is orthoscopic and athermal.

1.34<F′1/F′12<1.50

−1.65<F′1/F′14<−1.45

0.20<F′1/F′16<0.35

−1.10<F′1/F′18<−0.90

1.25<F′1/F′20<1.54

1.76<F′1/F′22<1.48

−2.45<F′1/F′24<−2.25

0.070<F′1/F′26<0.085

0.86<n12/n14=n12/n18=12/n24<0.98

0.74<n12/n16=n12/n26<0.82

0.90<n12/n20=n12/n22<1.10

1.45<OAL/F1<1.50

1.65<V12/V14=V12/V18=V12/V24<1.85

3.65<V12/V16=V12/V26<3.95

0.90<V12/V20=V12/V22<1.15

−4.30<dn/dT12/dn/dT14=dn/dT12/dn/dT18=dn/dT12/dn/dT24<−3.90

−0.75<dn/dT12/dn/dT16=dn/dT12/dn/dT26<−0.50

0.85<dn/dT12/dn/dT20=dn/dT12/dn/dT22<1.15

1.30<CTE12/CTE14=CTE12/CTE18=CTE12/CTE24<1.55

1.50<CTE12/CTE16=CTE12/CTE26<1.75

0.85<CTE12/CTE20=CTE12/CTE22<1.20

0.50<CTE12/CTEspacer<0.65

Wherein: F′1 is the focal length of the VNIR lens assembly 10 according to the present invention; F′10, F′11, F′12, F′13, F′14, F′15, F′16, F′17, are focal lengths of the first 12, second 14, third 16, fourth 18, fifth 20, sixth 22, seventh 24, and eighth 26 optical elements correspondingly; n12, n14, n16, n18, n20, n22, n24 and n26 are indices of refraction of the first 12, second 14, third 16, fourth 18, fifth 20, sixth 22, seventh 24, and eighth 26 optical elements correspondingly for the D spectral line (589.29 nm); OAL is the overall length of the lens assembly 10; dn/dT12, dn/dT14, dn/dT16, dn/dT18, dn/dT20, dn/dT22, dn/dT24 and dn/dT26 are refractive indices changes with temperature of the first 12, second 14, third 16, fourth 18, fifth 20, sixth 22, seventh 24, and eighth 26 optical elements correspondingly for the D spectral line (589.29 nm); and CTE12, CTE14, CTE16, CTE18, CTE20, CTE22, CTE24, CTE26 and CTEspacer are coefficients of thermal expansion of the first 12, second 14, third 16, fourth 18, fifth 20, sixth 22, seventh 24, and eighth 26 optical elements and mechanical spacers between them correspondingly.

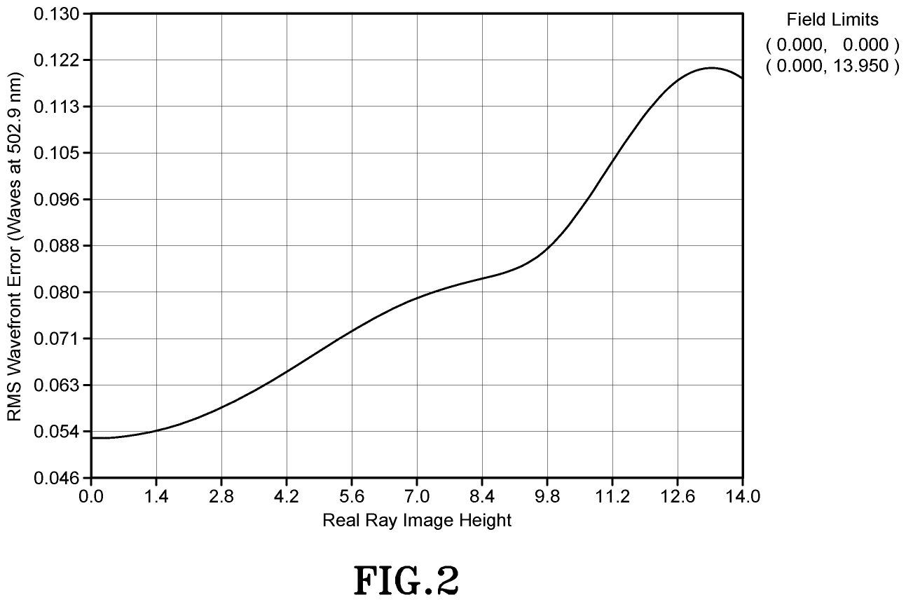

With reference to FIGS. 2-9, a series of graphs are provided showing the performance specifications of an exemplary lens assembly 10 as shown and described herein. In particular, with reference to FIG. 2, a wavefront analysis graph for the lens assembly 10 is shown indicating that the polychromatic wavefront is diffraction limited over the field of view.

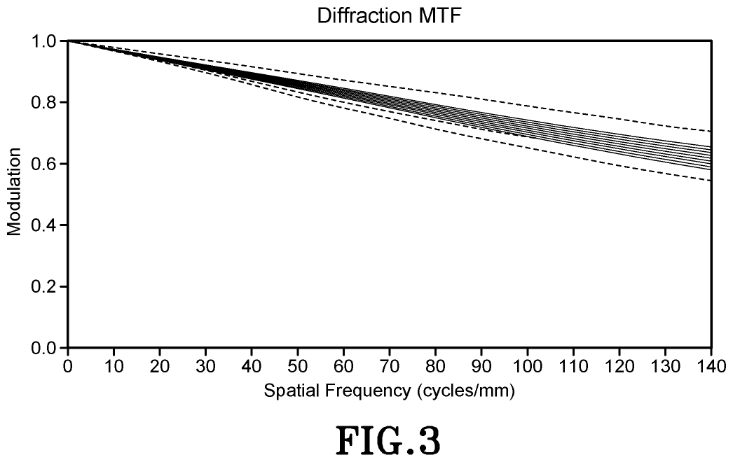

FIG. 3 shows a diffraction modulation transfer function (MTF) data graph indicating that the polychromatic MTF exceeds 0.45 across the field.

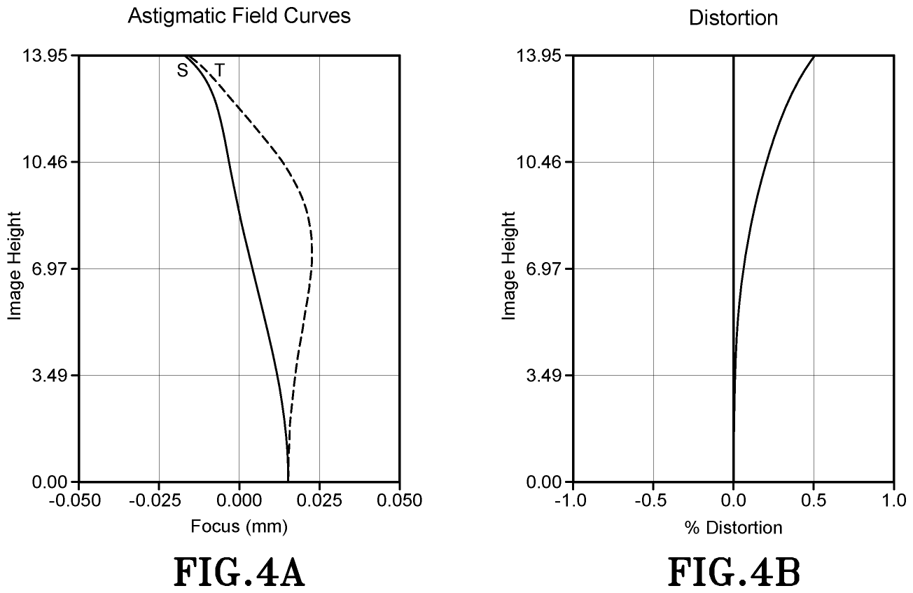

FIG. 4A shows that the correction of astigmatism of the lens assembly 10 across the field is less than DOF while FIG. 4B shows similar results for the correction of distortion of the lens assembly 10.

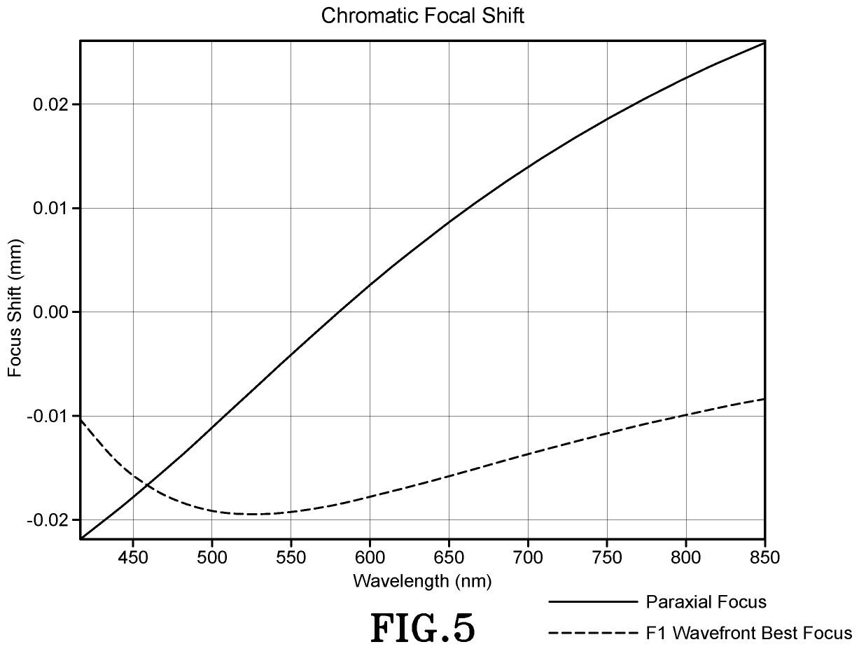

The graph in FIG. 5 shows a chromatic focus shift analysis indicating that the best focus for the entire spectral band does not exceed the diffraction limited depth of focus.

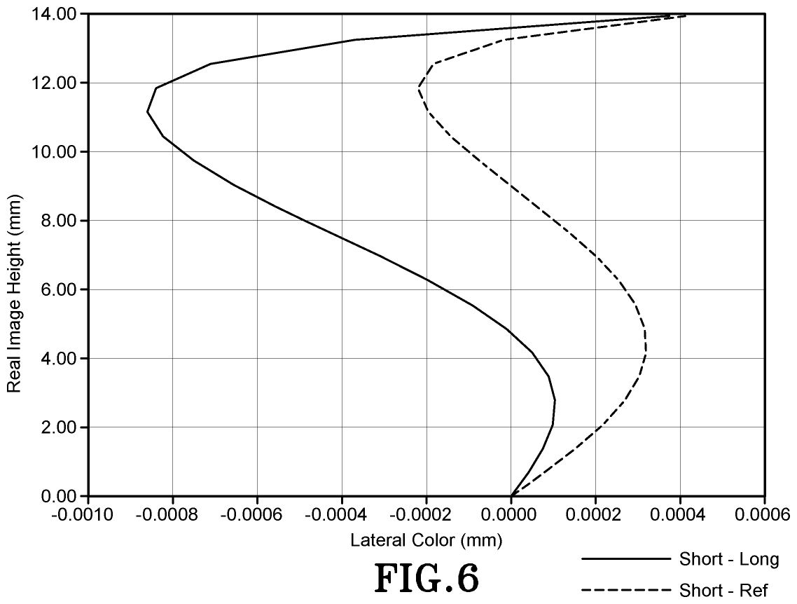

FIG. 6 provides that the lateral color is corrected across the field of view for the entire spectrum.

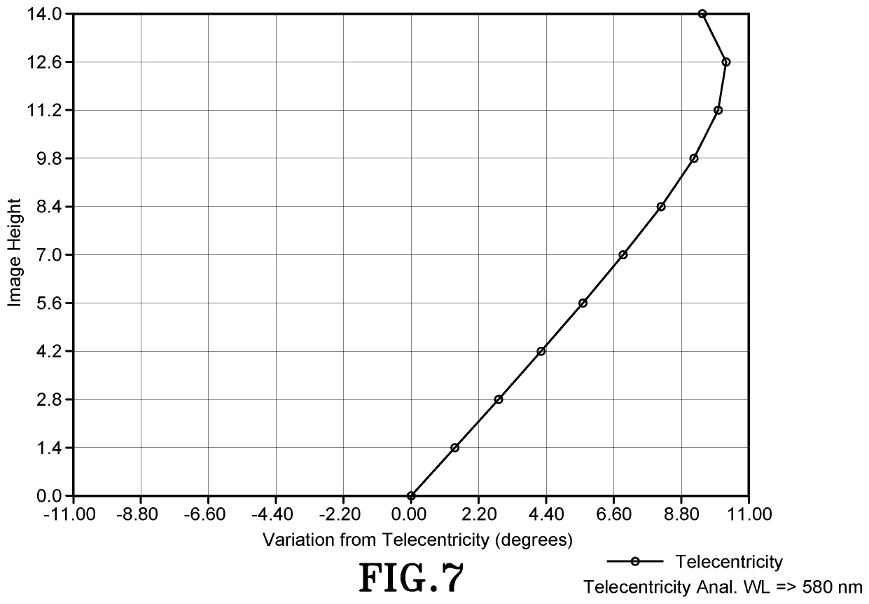

The data in FIG. 7 provides that the lens assembly 10 is nearly telecentric across the field of view and that the lack of telecentricity does not exceed 10%.

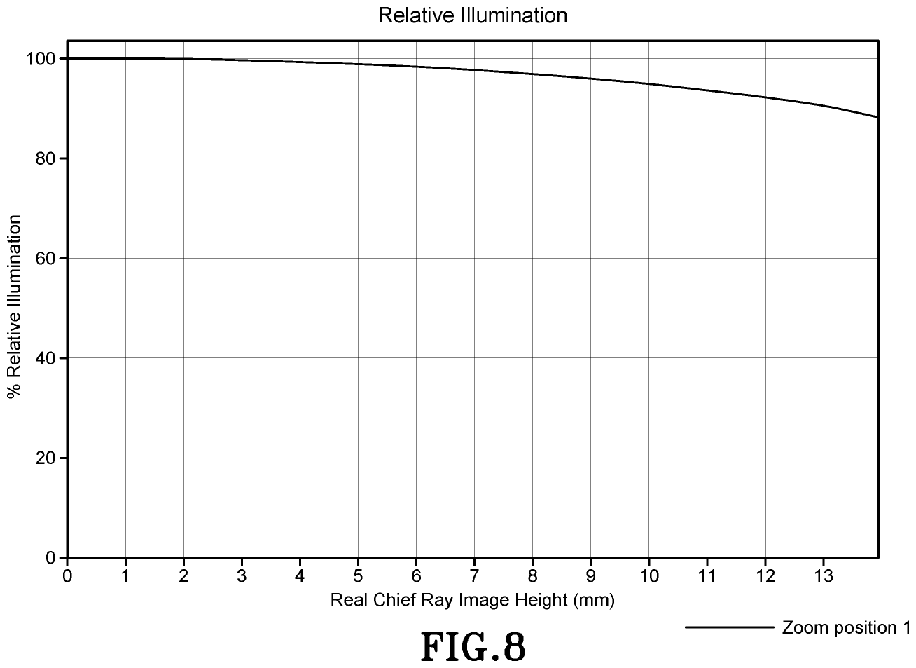

The graph in FIG. 8 indicates that the relative illumination across the field of view for the lens assembly 10 exceeds 85%.

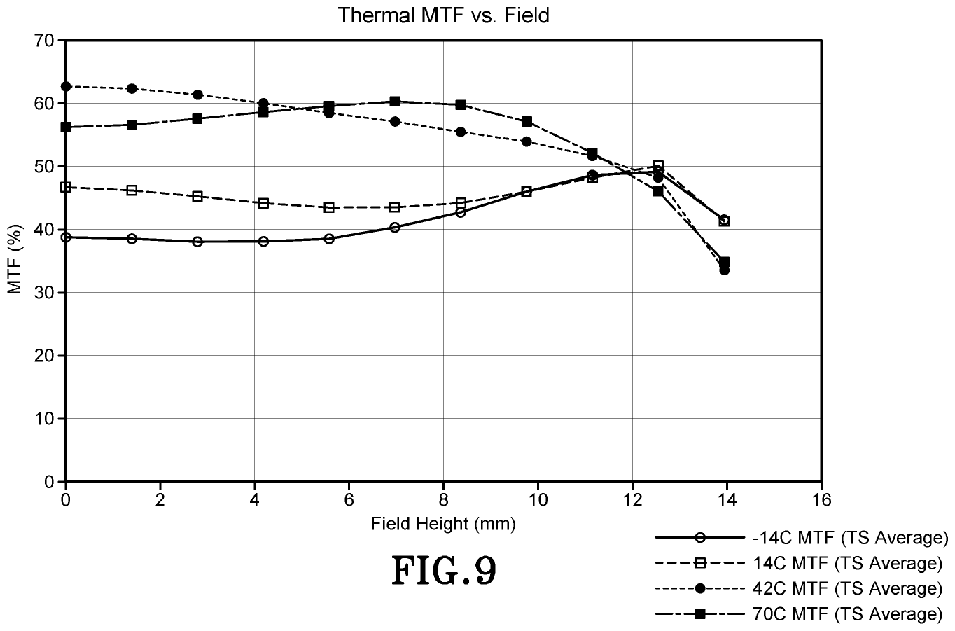

The graph presented as FIG. 9 provides that the polychromatic MTF exceeds 0.35 across the field of view through the temperature range between −14° C. and 70° C.

The prescription of the specific lens assembly 10 from FIG. 1 is provided here:

| Optical Element | Radius | Thickness | Surface Properties | |
|---|---|---|---|---|
| First Element | 34.49654 | 9.885051 | | |
| Side 12A | | | | |
| First Element | −51.93841 | 2.877511 | | |
| Side 12B | | | | |
| Second Element | −40.56790 | 4.000000 | | |
| Side 14A | | | | |
| Second Element | 51.89777 | 2.000000 | | |
| Side 14B | | | | |
| Third Element | 43.38976 | 6.355563 | | |
| Side 16A | | | | |
| Third Element | 50.33015 | 5.333695 | | |
| Side 16B | | | | |
| Fourth Element | −111.40851 | 4.000000 | | |
| Side 18A | | | | |
| Fourth Element | 55.32774 | 2.357144 | K: | 0.00 |
| Side 18B | | | A: | 0.600536E−05 |
| | | | B: | 0.863398E−09 |
| | | | C: | −0.637819E−11 |
| | | | D: | 0.174940E−13 |
| Fifth Element | 46.20419 | 12.940206 | | |
| Side 20A | | | | |
| Fifth Element | −37.42500 | 2.000000 | | |
| Side 20B | | | | |
| Sixth Element | 27.41734 | 14.612561 | | |
| Side 22A | | | | |
| Sixth Element | −61.52142 | 3.010629 | | |
| Side 22B | | | | |
| Seventh Element | −56.70763 | 4.0000000 | K: | 0.00 |
| Side 24A | | | A: | −0.140663E−04 |
| | | | B: | 0.212660E−07 |
| | | | C: | −0.219394E−10 |
| | | | D: | 0.275716E−13 |
| Seventh Element | 20.91139 | 13.662101 | | |
| Side 24B | | | | |
| Eighth Element | 37.21204 | 5.563336 | | |
| Side 26A | | | | |
| Eighth Element | 36.44367 | 4.503064 | K: | 0.00 |
| Side 26B | | | A: | −0.103988E−04 |
| | | | B: | 0.498166E−08 |
| | | | C: | −0.807608E−10 |
| | | | D: | 0.000000E+00 |

| | | |
|---|---|---|
| Window side 30A | Infinity | 0.710000 |
| Window side 30B | Infinity | 0.990000 |

Having thus described the elements and components in further detail, the operation and use of lens assembly 10 will not be discussed.

Lens assembly 10 may be utilized as a VNIR imaging lens for airborne operations including, but not limited to, object detection below a ground surface or other similar engagements. As discussed above, lens assembly 10 may have a focal point ratio (or F #) of approximately 2.8 with an angular full field of view of 24°. Lens assembly 10 may be further corrected from monochromatic and chromatic aberrations over the VNIR wavelength range between 870 nanometers to 400 nanometers. According to one aspect, the focal length of lens assembly 10 may be 66 millimeters. The elements of lens assembly 10 may provide a nearly telecentric lens with telecentricity less than 10% while further providing orthoscopic features with a distortion less than 0.5% and passive athermality within a range of −14° C. to 70° C. The overall length of lens assembly 10 may be less than 100 millimeters (˜99 mm).

As employed, lens assembly 10 may operate similar to other common VNIR lenses, namely, light may enter lens assembly 10 through aperture stop 28 and pass through each of first through eighth elements 12-26 and the first and second surfaces thereof, respectively. In doing so, the image may be focused on the FPA 32 as temperature and other conditions change the shapes and positions of first through eighth, elements 12-26 may likewise change and/or fluctuate. This may further cause changes to the focusing and position of the images. As discussed above, the specific materials for each of first through eighth element are selected for their coefficients of thermal expansion which provides that lens assembly 10 does not need to include thermal adjustment mechanisms as the focus position changes within the required temperature range. Specifically, the change in focus positions stays inside the depth of focus of lens assembly 10.

As further discussed above, the mutual combination of the refractive indices and dispersions of each of first through eighth optical elements 12-26 may allow for achieving the wide field of view, low focal ratio, orthoscopic distortion, and achromatic correction of lens assembly 10 along with a field curvature correction. Having high order aspheres on second surface 18B of fourth optical element 18, on first surface 24A of seventh element 24, and on second surface 26B of the eighth element 26 allows for further correction of high order spherical aberration, coma, residual astigmatism, and distortion.

Once the light passes through the first thorough eighth optical elements 12-26, it may be directed to the FPA 32 where it may be detected and processed to generate an image according to the desired objective of the implementation of lens assembly 10. For example, where lens assembly 10 is employed in a shearography application, the FPA 32 (including processor(s) in communication therewith) may detect and generate a shearogram from the image on the FPA 32.

The foregoing description of the embodiments has been presented for the purposes of illustration and explanation. It is not intended to be exhaustive or to limit the invention to the precise form disclosed. It will be understood that many modifications and variations may be made to this disclosure by a person of skill in the art. Accordingly, it will be understood that the scope of the present disclosure be limited not by this detailed description, but rather by the claims appended hereto.

Although elements and/or operations are depicted in the drawings in a particular order, this should not be understood as requiring that such elements and/or operations be arranged or performed in the particular order shown or in sequential order, or that all illustrated elements and/or operations be present and/or performed, to achieve desirable results.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

“Logic”, as used herein, includes but is not limited to hardware, firmware, software and/or combinations of each to perform a function(s) or an action(s), and/or to cause a function or action from another logic, method, and/or system. For example, based on a desired application or needs, logic may include a software controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

1. A visible and near infrared (VNIR) lens assembly comprising:
a plurality of first optical elements, each having a positive optical power;
a plurality of second optical elements, each having a negative optical power;
a physical aperture stop in front of the plurality of first and second optical elements; and
an image detector behind the plurality of first and second optical elements;
wherein at least one optical element of the plurality of first optical elements is formed of a first optical glass type, at least another optical element of the plurality of first optical elements is formed of a second optical glass type, and at least one of the plurality of second optical elements is formed of a third optical glass, wherein none of the plurality of second optical elements are formed of the first or second glass types, and wherein each of the first, second, and third optical glass types are selected according to their coefficient of thermal expansion.

2. The VNIR lens assembly of claim 1 wherein the first and second plurality of optical glasses further comprises:
eight total optical elements with five optical elements in the first plurality of optical elements having a positive optical power and three optical elements in the second plurality of optical elements having a negative optical power.

3. The VNIR lens assembly of claim 2 wherein the eight total optical elements of the first and second plurality of optical elements are arranged in order from the aperture to the image detector as a first optical element having a positive optical power, a second optical element having a negative optical power, a third optical element having a positive optical power, a fourth optical element having a negative optical power, a fifth optical element having a positive optical power, a sixth optical element having a positive optical power, a seventh optical element having a negative optical power, and an eighth optical element having a positive optical power.

4. The VNIR lens assembly of claim 3 wherein:
the first optical glass type further comprises a fluor crown optical glass;
the second optical glass type further comprises a dense flint optical glass; and
the third optical glass type further comprises a crownflint optical glass.

5. The VNIR lens assembly of claim 4 wherein the first, fifth, and sixth optical elements are made from the first optical glass type, the third and eighth optical elements are made from the second optical glass type, and the second, fourth, and seventh optical elements are made from the third optical glass type.

6. The VNIR lens assembly of claim 4 wherein the first optical glass type is Schott optical glass N-FK58, the second optical glass type is Schott optical glass N-SF57HTUltra, and the third optical glass type is Schott optical glass N-KF9.

7. The VNIR lens assembly of claim 3 wherein the first optical element further comprises:
a double convex lens having a first surface oriented towards the aperture stop and a second surface opposite therefrom.

8. The VNIR lens assembly of claim 3 wherein the second optical element further comprises:
a double concave lens having a first surface oriented towards the aperture stop and a second surface opposite therefrom.

9. The VNIR lens assembly of claim 3 wherein the third optical element further comprises:
a positive meniscus lens having a first surface oriented towards the aperture stop and a second surface opposite therefrom;
wherein the second surface of the third optical element is a concave surface of the positive meniscus.

10. The VNIR lens assembly of claim 3 wherein the fourth optical element further comprises:
a double concave lens having a first surface oriented towards the aperture stop and a second surface opposite therefrom;
wherein the second surface of the fourth optical element is aspherical.

11. The VNIR lens assembly of claim 3 wherein the fifth optical element further comprises:
a double convex lens having a first surface oriented towards the aperture stop and a second surface opposite therefrom.

12. The VNIR lens assembly of claim 3 wherein the sixth optical element further comprises:
a double convex lens having a first surface oriented towards the aperture stop and a second surface opposite therefrom.

13. The VNIR lens assembly of claim 3 wherein the seventh optical element further comprises:
a double concave lens having a first surface oriented towards the aperture stop and a second surface opposite therefrom;
wherein the first surface of the seventh optical element is aspherical.

14. The VNIR lens assembly of claim 3 wherein the eighth optical element further comprises:
a positive meniscus lens having a first surface oriented towards the aperture stop and a second surface opposite therefrom;
wherein the second surface of the eighth optical element is a concave surface of the positive meniscus and is aspherical.

15. The VNIR lens assembly of claim 3 wherein the lens assembly further comprises:
an orthoscopic lens with residual distortion not exceeding 0.5% over a full field of view;
an overall length less than 100 mm as measured from the first element to the image detector; and
a focal point ratio of 2.8.

16. The VNIR lens assembly of claim 15 wherein the lens assembly is achromatic over a spectral range from 870 nm to 400 nm, is passively athermal for the range of −14° C. to 70° C., and has a resolution of 3.45 micrometers at the image detector.

17. A visible and near infrared (VNIR) orthoscopic lens assembly comprising:
a physical aperture stop defining an entrance pupil;
a first optical element having a positive optical power, the first optical element being a double convex lens;
a second optical element having a negative optical power, the second optical element being a double concave lens;
a third optical element having a positive optical power, the third optical element being positive meniscus lens having a first surface oriented towards the aperture stop and a second surface opposite therefrom, wherein the second surface of the third optical element is a concave surface of the positive meniscus;
a fourth optical element having a negative optical power, the fourth optical element being a double concave lens having a first surface oriented towards the aperture stop and a second surface opposite therefrom, wherein the second surface of the fourth optical element is aspherical;
a fifth optical element having a positive optical power, the fifth optical element being a double convex lens;
a sixth optical element having a positive optical power, the sixth optical element being a double convex lens;
a seventh optical element having a negative optical power, the seventh optical element being a double concave lens having a first surface oriented towards the aperture stop and a second surface opposite therefrom, wherein the first surface of the seventh optical element is aspherical;
an eighth optical element having a positive optical power, the eighth optical element being a positive meniscus lens having a first surface oriented towards the aperture stop and a second surface opposite therefrom, wherein the second surface of the eighth optical element is a concave surface of the positive meniscus and is aspherical; and
an image detector;
wherein the lens assembly has an overall length less than 100 mm as measured from the first optical element to the image detector and a focal point ratio of 2.8; and
wherein the lens assembly is achromatic over a spectral range from 870 nm to 400 nm and is passively athermal for the range of −14° C. to 70° C.

18. A method comprising:
receiving light through a physical aperture stop of a lens assembly;
directing the light through a first plurality of optical elements, wherein each optical element of the first plurality of optical elements has a positive optical power with at least one element of the first plurality of optical elements formed of a first optical glass type and at least another element of the first plurality of optical elements formed of a second optical glass type;
directing the light through a second plurality of optical elements, wherein each optical element of the first plurality of optical elements has a negative optical power with at least one of the second plurality of optical elements formed of a third optical glass type, wherein none of the plurality of second optical elements are formed of the first or second glass types;
detecting the light with an image detector; and
generating an image from the image detector.

19. The method of claim 18 wherein directing the light through the first and second pluralities of optical elements further comprises:
directing the light through a first optical element having a double convex shape and a positive optical power;
directing the light through a second optical element having a double concave shape and a negative optical power;
directing the light through a third optical element having a positive meniscus shape and a positive optical power, the third optical element having a first surface and a second surface wherein the second surface is a concave surface of the positive meniscus;
directing the light through a fourth optical element having a double concave shape and a negative optical power, wherein a second surface of the fourth optical element is aspherical;
directing the light through a fifth optical element having a double convex shape and a positive optical power;
directing the light through a sixth optical element having a double convex shape and a positive optical power;
directing the light through a seventh optical element having a double concave shape and a negative optical power, wherein a first surface of the seventh optical element is aspherical; and
directing the light through an eighth optical element having a double convex shape and a positive optical power, the eighth optical element having a first surface and a second surface wherein the second surface is a concave surface of the positive meniscus and is aspherical.

20. The method of claim 19 wherein the lens assembly further comprises:
an orthoscopic lens with residual distortion not exceeding 0.5% over a full field of view;
an overall length less than 100 mm as measured from the first element to the image detector; and
a focal point ratio of 2.8; wherein the lens assembly is achromatic over a spectral range from 870 nm to 400 nm, is passively athermal for the range of −14° C. to 70° C., and has a resolution of 3.45 micrometers at the image detector.
